(19) United States
(12) Patent Application Publication
(10) Pub. No.: US 2023/0102199 A1
(43) Pub. Date: Mar. 30, 2023

(54) METHOD FOR PREPARING LEAD IODIDE AND PEROVSKITE FILM

(71) Applicant: Industrial Technology Research Institute, Hsinchu (TW)

(72) Inventors: Pei-Ting Chiu, Hsinchu (TW); Yung-Liang Tung, Hsinchu (TW); Shih-Hsiung Wu, Hsinchu (TW); Kuo-Wei Huang, Hsinchu (TW); Jung-Pin Chiou, Hsinchu (TW); Jen-An Chen, Hsinchu (TW); Qiao-Zhi Guan, Hsinchu (TW)

(21) Appl. No.: 17/574,140

(22) Filed: Jan. 12, 2022

(30) Foreign Application Priority Data
Sep. 30, 2021 (TW) 110136555

(51) Int. Cl. H01G 9/00; C01G 21/16; H01G 9/20; H01L 51/00; H01L 51/42

(52) U.S. Cl. CPC H01G 9/0036; C01G 21/16; H01G 9/2009; H01L 51/0002; H01L 51/0026; H01L 51/4253; H01L 51/0077; C01P 2002/74; C01P 2002/72; C01P 2004/02

(57) ABSTRACT

Provided is a method for preparing lead iodide, which controls the crystal form of lead iodide through temperature, including: dissolving a lead compound in a first acid solution and adding an iodine compound to form a reaction solution including the first lead iodide; and heating the reaction solution to a temperature of 60° C. or more and standing at a constant temperature, to obtain the second lead iodide, wherein a peak intensity of the (003) crystal plane of the second lead iodide is greater than or equal to a peak intensity of the (110) crystal plane. Provided is also a method for preparing the perovskite film.

### CROSS-REFERENCE TO RELATED APPLICATIONS

This application claims priority to Taiwan Application Serial No. 110136555, filed on Sep. 30, 2021. The entirety of the application is hereby incorporated by reference herein and made a part of this application.

### TECHNICAL FIELD

This disclosure relates to a method for preparing lead iodide, and relates to a method for preparing perovskite film.

### BACKGROUND

Organic-inorganic hybrid perovskites have been found to be a material with excellent photoelectric properties, which can greatly improve the power conversion efficiency of perovskite solar cells. The structure of perovskite can be represented by ABX₃, and organic-inorganic hybrid perovskite materials mainly include organic ammonium (MA) or amidine ion (FA) as the central cation of the A site, and the B site cation is mainly lead. There are different advantages and disadvantages with the use of different types of ions for making organic-inorganic hybrid perovskite materials. For example, MAPbI₃ is easy to produce but has poor thermal stability and shorter lifespan; while FAPbI₃ has higher thermal stability and power conversion efficiency, but the photoactive black phase (a phase) is thermodynamically unstable at room temperature, and it is easy to form a non-photoactive yellow phase (δ phase), which leads to complex production conditions such as formulation factors. At present, it has been found that by hybridizing multiple A-site central cations, both efficiency and stability can be achieved at the same time. In addition to the effect of the central cation at the A site, the (BX₆)⁴⁻ octahedron surrounding the central cation as a structural scaffold also greatly affects the properties of the perovskite.

In addition, the existing literatures have confirmed that the raw materials in the perovskite precursor solution form a colloidal dispersion instead of being completely dissolved. Therefore, it is considered that the original characteristics of raw materials can have an impact on the properties of colloids, which can be used to control the efficiency of perovskite products.

There remains a long way to go for improvement in the power conversion efficiency of perovskite solar cells and the industry expects the development of perovskite solar cells that will continue to grow.

### SUMMARY

This disclosure provides a method for preparing lead iodide, which includes: adding an iodine compound to a first acid solution, in which a lead compound is dissolved, to form a reaction solution including a first lead iodide; and heating the reaction solution to a temperature of 60° C. or above and standing at a constant temperature, to obtain a second lead iodide, wherein a peak intensity of a (003) crystal plane of the second lead iodide is greater than or equal to a peak intensity of a (110) crystal plane.

This disclosure also provides a preparation method of perovskite film, which includes: formulating a ternary perovskite precursor solution from a lead iodide, wherein a peak intensity of a (003) crystal plane of the lead iodide is greater than or equal to a peak intensity of a (110) crystal plane; and coating the ternary perovskite precursor solution on a substrate to form a ternary perovskite film.

### BRIEF DESCRIPTION OF THE DRAWINGS

FIGS. 1 to 6 are the X-ray diffraction (XRD) patterns of lead iodide prepared in Examples 1 to 6 of this disclosure.

FIGS. 7 and 8 are the XRD patterns of lead iodide prepared in Comparative examples 1 and 2 of this disclosure.

FIG. 9 is a graph of short-circuit current density (Jsc) vs. open-circuit voltage (Voc) of the perovskite solar cell element of Test Example 1 of this disclosure.

FIG. 10 is the XRD pattern of the lead iodide prepared in Example 11 of this disclosure.

FIG. 11A is a microscope photograph of lead iodide prepared in Example 2 of this disclosure, and FIG. 11B is a microscope photograph of lead iodide prepared in Example 12 of this disclosure.

### DETAILED DESCRIPTION

The execution modes of this disclosure are illustrated by particular embodiments, and a person having the ordinary skill in the technical field to which this disclosure belongs can readily appreciate the scope and efficacy of this disclosure based on the content recorded herein. However, the embodiments recorded herein are not intended to limit this disclosure. The technical features or schemes listed can be combined with each other. This disclosure can be implemented or applied by other different execution modes. Details recorded herein can be altered or modified differently according to different viewpoints and applications without departing from this disclosure.

Unless stated otherwise, the term “comprising”, “including”, “containing” or “having” particular elements used herein means that other elements such as units, components, structures, regions, parts, devices, systems, steps or connection associations can be also included rather than excluded.

Unless expressly stated otherwise, the singular forms “a”, “an” and “the” also include the plural forms, and the “or” and “and/or” can be used interchangeably herein.

The value ranges recited herein are inclusive and can be combined, and any value falling into the value range recited herein can be used as the upper or lower limit to derive a subrange; for example, a value range of “60° C. to 160° C.” should be understood to include any subrange from a lower limit of 60° C. to an upper limit of 160° C., e.g., subranges of 100° C. to 160° C., 60° C. to 120° C., 100° C. to 120° C. and so on. In addition, a value should be considered to be included in the range of this disclosure if the value falls into a range recited herein (e.g., 100° C. falls into the range from 0° C. to 160° C.).

This disclosure provides a method for preparing lead iodide having a specific crystal form. When the perovskite precursor solution is formed, the crystal form of lead iodide affects the formed colloids, thereby regulating the photoelectric properties of the perovskite film, and endowing a more excellent power conversion efficiency. The first embodiment of this disclosure is a method for preparing lead iodide, in which the crystal form of lead iodide is controlled through temperature during the preparation process, and the preparation steps include:

adding an iodine compound to a first acid solution, in which a lead compound is dissolved, to form a reaction solution including a first lead iodide; and

heating the reaction solution to a temperature of 60° C. or above and standing at a constant temperature, to obtain a second lead iodide,

wherein a peak intensity of a (003) crystal plane of the second lead iodide is greater than or equal to a peak intensity of a (110) crystal plane.

In this disclosure, suitable compounds for the lead compounds and iodine compounds are not specifically limited. For example, the lead compounds may include lead acetate, lead nitrate, lead hydroxide, lead oxide, lead chloride, lead carbonate, lead silicate, lead sulfate, or a combination thereof; and the iodine compound can also be exemplified as potassium iodide, sodium iodide, lithium iodide, rubidium iodide, cesium iodide, strontium iodide, calcium iodide, barium iodide, magnesium iodide, or a combination thereof. In order to ensure that the iodine compounds are dissolved and properly associated with the lead compound to facilitate subsequent reactions, the iodine compound may be dissolved in water first, and then the iodine compound aqueous solution is added to the first acid solution.

In this disclosure, the lead compound may be dissolved in the first acid solution, then the iodine compound is added followed by a reaction to form lead iodide (first lead iodide). Therefore, it can be understood that the first acid solution can be used as long as the first acid solution dissolves lead compounds and provide an acidic reactive condition for the lead compounds and the iodine compounds. The specific acidic solution is not limited as long as this dissolvable function can be achieved. In this disclosure, the so-called acidity is exemplified as pH values of between 1 to 5. In other embodiments, the pH values may also be between 2 to 5 or 2 to 4, specifically, the pH value may be 1, 1.5, 2, 2.5, 3, 3.5, 4, 4.5, or 5. Specific examples of the first acid solution are, for example, acetic acid, hydrochloric acid, sulfuric acid, nitric acid, phosphoric acid, boric acid, or a combination thereof.

During the process of adding the lead compound and the iodine compound to form the reaction solution, stiffing can be applied to promote the dissolution of the lead compound. The first lead iodide is obtained from the reaction at this stage. After that, the reaction solution is heated up. In this stage of the process, the first lead iodide is converted into the second lead iodide with an increase in temperature. In this disclosure, after the temperature is increased, it is necessary to stand still at a constant temperature to facilitate crystallization. As the temperature increases, this disclosure has found that the crystal form of lead iodide (second lead iodide) can be controlled by the temperature of the reaction solution. In this disclosure, the temperature of the reaction solution is increased to 60° C. or higher, and it may also be increased to 60° C. to 160° C., 80° C. to 120° C., 80° C. to 160° C., 100 to 120° C., or 100 to 160° C., for example, 60° C., 70° C., 80° C., 90° C., 100° C., 110° C., 120° C., 130° C., 140° C., 150° C. and 160° C. The crystal form of lead iodide formed in this temperature range meets the needs, and the specific crystal form is described later in this disclosure. Said standing at a constant temperature is beneficial to the reaction between iodine compounds and lead compounds. The time of standing at a constant temperature may be between 1 to 3 hours, for example, 1, 1.5, 2, 2.5, or 3 hours. The time of standing at a constant temperature is at least 1 hour and the specific crystal form of this disclosure can be obtained. When the time of standing at a constant temperature is too long, lead iodide may be oxidized due to prolonged exposure to high temperature solution.

In a specific embodiment, after standing at a constant temperature, the second lead iodide is obtained through cooling, for example, removing a heat source and then cooling to 20 to 30° C. (room temperature). Once the second lead iodide is obtained, it is rinsed repeatedly with water until it is neutral.

This disclosure further includes a second embodiment, which is another preparation method of lead iodide, including:

adding an iodine compound to a first acid solution, in which a lead compound is dissolved, to form a first solution;

reacting the first solution to form a first lead iodide;

adding a second acid solution to the first solution to form a second solution; and

increasing the temperature of the second solution (i.e., the first solution containing the second acid solution) to 60° C. or above and standing at a constant temperature to obtain a second lead iodide.

It can be understood that the preparation method of lead iodide in the second embodiment is based on the preparation method of lead iodide in the first embodiment and further adding a step involving the second acid solution. Adding the second acid solution is after the formation of the first lead iodide and before the increase of the temperature. The attachment of impurities to the first lead iodide is reduced by adding the second acid solution, and the conversion of the first lead iodide to the second lead iodide is more complete. The second acid solution may be the same as the first acid solution in terms of cost, controllability, etc. The same as stated herein can refer to the same composition but the different concentration, or the same composition and concentration. However, depending on the needs, the second acid solution can also be selected to have a composition different from that of the first acid solution. In a specific embodiment, the first acid solution and the second acid solution both are acetic acid solutions with a pH of 3.

In a specific embodiment, the reacted first solution is diluted with the second acid solution, so that the concentration of the first lead iodide formed in the first solution decreases. A decrease in the concentration is beneficial to subsequent crystallization, and the first lead iodide serves as the seed crystal for the subsequent second stage reaction. For example, the concentration of the first lead iodide in the second solution is less than 2 mM, and can also be less than 1 mM or 0.5 mM, such as 1.99 mM, 1.9 mM, 1.8 mM, 1.7 mM, 1.6 mM, 1.5 mM, 1.4 mM, 1.3 mM, 1.2 mM, 1.1 mM, 1 mM, 0.95 mM, 0.9 mM, 0.8 mM, 0.7 mM, 0.6 mM, 0.5 mM, 0.4 mM, 0.3 mM, 0.2 mM, or 0.1 mM. The lead iodide may not react sufficiently when the concentration of the lead iodide is too high, and the overall crystallization is affected, which is not conducive to obtaining the specific crystal form of this disclosure.

This disclosure finds that by controlling the reaction temperature of the iodine compound and the lead compound, the crystal form of the prepared lead iodide can be effectively controlled. In particular, the peak intensity of the (003) crystal plane in the lead iodide XRD pattern can be greater than or equal to (110) the peak intensity of the crystal plane. Hereinafter, the peak of the (003) crystal plane is also referred to as c-peak, and the peak of the (110) crystal plane is also referred to as d-peak.

In this disclosure, that the peak intensity of c-peak is greater than or equal to the peak intensity of d-peak can be further defined as the peak intensity of c-peak relative to the peak intensity of d-peak is 1 time or more, 2 times or more, 2.5 times or more, or 3 times or more. For example, the peak intensity of the c-peak relative to the peak intensity of d-peak is 1, 1.25, 1.5, 1.75, 2, 2.5, 3, 3.5, 4, 4.5, 5, 6, 7, 8, 9, 10, 11, 12, 13, 14, 15, 16, 17, 18, 19, 20, 25, 30, 35, or 40 times. In a specific embodiment, the intensity of the c-peak relative to the intensity of the d-peak is more than 2.5 times, and at this time, the Z-axis horizontal arrangement represented by the c-peak is much greater than the XY-axis lateral arrangement represented by the d-peak. The performance of the perovskite film is enhanced by the horizontal arrangement, such as the power conversion efficiency can be optimized.

The method for preparing lead iodide in this disclosure can control the relative intensity of the peak intensity of the (001) crystal plane and the peak intensity of the (101) crystal plane in addition to the aforementioned relative intensity of the c-peak intensity and the d-peak intensity. Hereinafter, the peak of the (001) crystal plane is referred to as a-peak, and the peak of the (101) crystal plane is also referred to as b-peak. Specifically, this disclosure controls that the peak intensity of a-peak is greater than or equal to the peak intensity of b-peak.

In this disclosure, the peak intensity of a-peak is greater than or equal to the peak intensity of b-peak can be further defined as the peak intensity of a-peak relative to the peak intensity of b-peak is 1 time, 2 times, 5 times, or 10 times or more. For example, the peak intensity of a-peak relative to the peak intensity of b-peak is 1, 1.25, 1.5, 1.75, 2, 2.5, 3, 3.5, 4, 4.5, 5, 6, 7, 8, 9, 10, 11, 12, 13, 14, 15, 16, 17, 18, 19, 20, 25, 30, 35, or 40 times. In a specific embodiment, the peak intensity of a-peak is more than twice the peak intensity of b-peak, and at this time, the Z-axis horizontal arrangement represented by a-peak is much larger than the XY-axis lateral arrangement represented by b-peak. The performance of the perovskite film is enhanced by the horizontal arrangement, such as the power conversion efficiency can be optimized.

In this disclosure, the crystal form of lead iodide is classified as follows:

Type I crystal form: the peak intensity of c-peak is greater than or equal to the peak intensity of d-peak, and the peak intensity of a-peak is greater than or equal to the peak intensity of b-peak;

Type II crystal form: the peak intensity of c-peak is greater than or equal to the peak intensity of d-peak, and the peak intensity of a-peak is less than the peak intensity of b-peak;

Type III crystal form: the peak intensity of c-peak is less than the peak intensity of d-peak, and the peak intensity a-peak is greater than or equal to the peak intensity of b-peak; and

Type IV crystal form: the peak intensity of c-peak is less than the peak intensity of d-peak, and the peak intensity of a-peak is less than the peak intensity of b-peak.

By preparing the above-mentioned specific Type I and Type II crystal forms of lead iodide, the lead iodide can be particularly suitable for forming a ternary perovskite film.

A third embodiment of this disclosure is a method for preparing a perovskite film, including:

formulating a ternary perovskite precursor solution from lead iodide, wherein the peak intensity of a (003) crystal plane of the lead iodide is greater than or equal to a peak intensity of a (110) crystal plane; and

coating the ternary perovskite precursor solution on a substrate to form a ternary perovskite film.

In the method for preparing the perovskite film, the lead iodide has specific Type I and Type II crystal forms, and it is proved in this disclosure that using the specific crystal form of lead iodide as a raw material for perovskite can optimize the power conversion efficiency and other properties. In order to obtain the specific Type I and Type II crystal forms, the methods for preparing lead iodide in the first and second embodiment described above can be used.

Said coating, as long as the ternary perovskite precursor solution can be uniformly distributed on the substrate, is included in the scope of this disclosure. In a specific embodiment, the coating is spin coating or blade coating.

In the method for preparing the perovskite film, the preparation method further includes forming the ternary perovskite film by an anti-solvent method or a heating method.

Said ternary perovskite is represented by ABX₃, wherein A is a monovalent cation including M₁, M₂ and M₃, and M₁ is a C₁₋₂₀ alkyl or C₆₋₂₀ aryl substituted or unsubstituted amine compound, M₂ is a C₁₋₂₀ alkyl or C₆₋₂₀ aryl substituted or unsubstituted amidine compound, M₃ is at least one selected from the group consisting of Cs, Rb, Li and Na, B represents Pb, and X is at least one selected from the group consisting of halogen, SCN, and OCN.

In a specific embodiment, the ternary perovskite is (MAₓA_{y}Cs_{1-x-y})Pb(BrₐI₁₋ₐ)₃, wherein MA is CH₃NH₃⁺, FA is HC(═NH)NH₂⁺, 0<x<1, 0<y<1, 1-x-y is greater than 0, and 0≤a≤1.

In a specific embodiment, the lead iodide, lead bromide, formamidine hydroiodide, methylammonium bromide, and cesium iodide are mixed with a solvent to formulate the ternary perovskite precursor solution. The above-mentioned raw materials do not really dissolve like dissociation but form a colloidal dispersion with the solvent. The colloid formed from the raw materials will affect the properties of the formed ternary perovskite.

In this disclosure, the solvent used for mixing with the above-mentioned perovskite raw materials is not limited, and conventional solvents can be selected depending on the needs. For example, the suitable solvent includes dimethyl sulfoxide, dimethylformamide, y-butyrolactone, N-methyl-2-pyrrolidone, or a combination thereof.

In this disclosure, the crystal form of lead iodide can be controlled through temperature so that the peak intensity of the (003) crystal plane is greater than or equal to the peak intensity of the (110) crystal plane, and/or the peak intensity of the (001) crystal plane is further greater than or equal to the peak intensity of the (101) crystal plane.

The use of lead iodide having a specific crystal form as the raw material of perovskite, thereby suppressing the yellow phase of perovskite, is particularly suitable for improving the efficiency of the ternary perovskite.

This disclosure will describe further in detail with reference to the following examples, but these examples are by no means intended to limit the scope of this disclosure.

### Example 1

3.793 g of lead acetate trihydrate was taken and dissolved in the acetic acid solution with a pH value of 3 with stirring; another 3.32 g of potassium iodide was taken and dissolved in 15 ml of pure water, then added to the aforementioned acetic acid solution at room temperature to form the first solution, and the first lead iodide was formed.

500 ml of an acetic acid solution with a pH value of 3 was taken and added to the reacted reaction solution to form a second solution. The second solution was placed into the reactor, heated to 160° C., then the temperature was kept for 2 hours to react, and then slowly cooled to room temperature. The reacted second solution was centrifuged, and the precipitate (i.e. the second lead iodide) was rinsed with water and repeated several times until the pH value reached 7.

### Examples 2 to 6, Comparative Examples 1 and 2

Examples 2 to 6, Comparative examples 1 and 2 prepared lead iodide according to the preparation method described in Example 1, and the differences were in the pH value and temperature, as shown in Table 1 below.

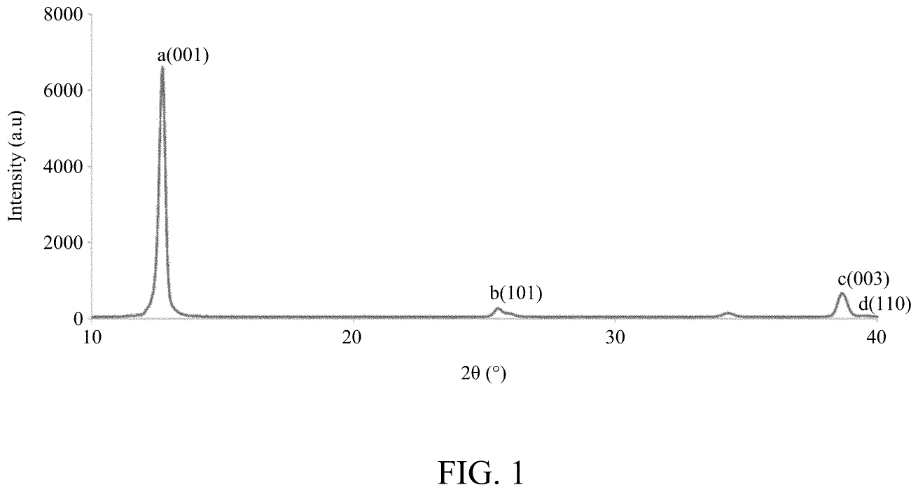

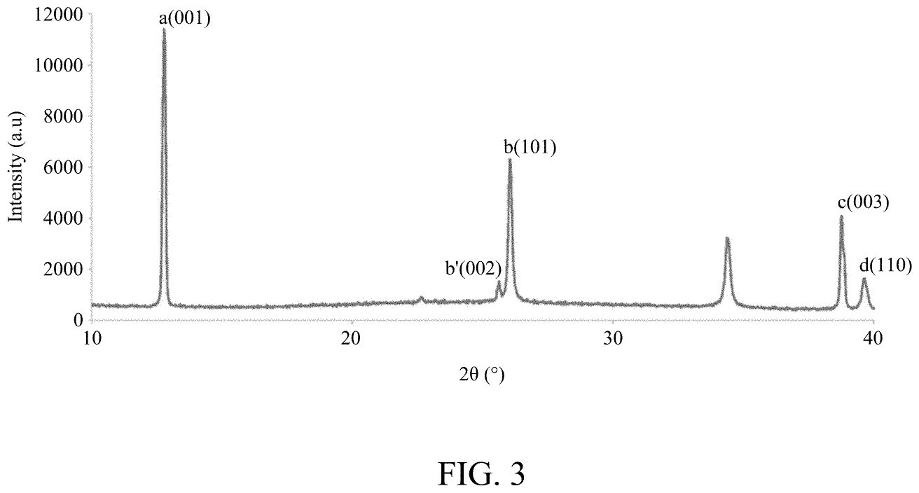

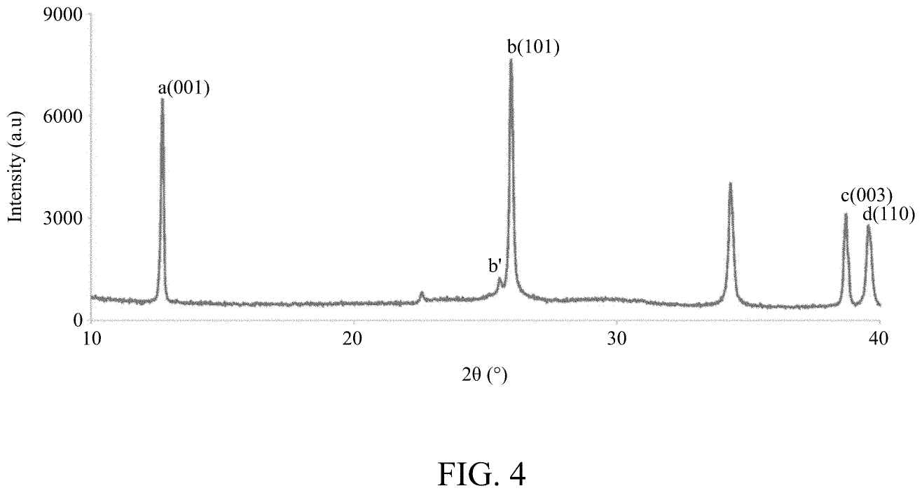

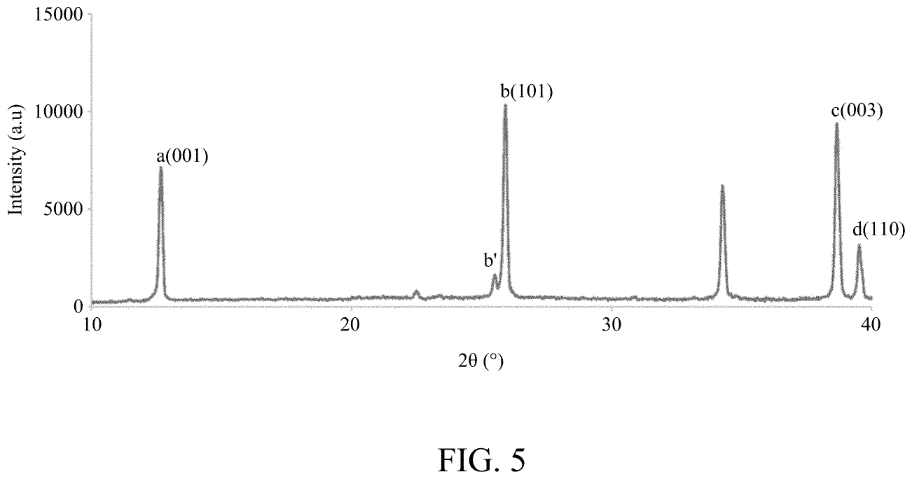

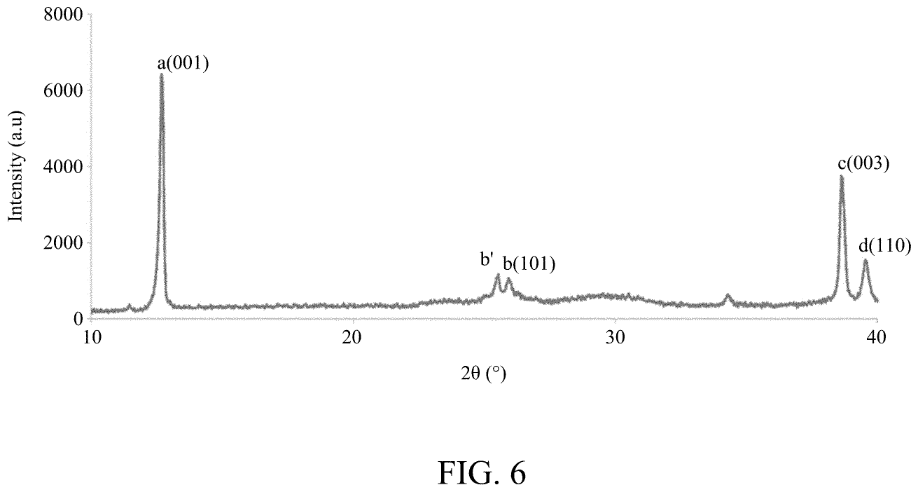

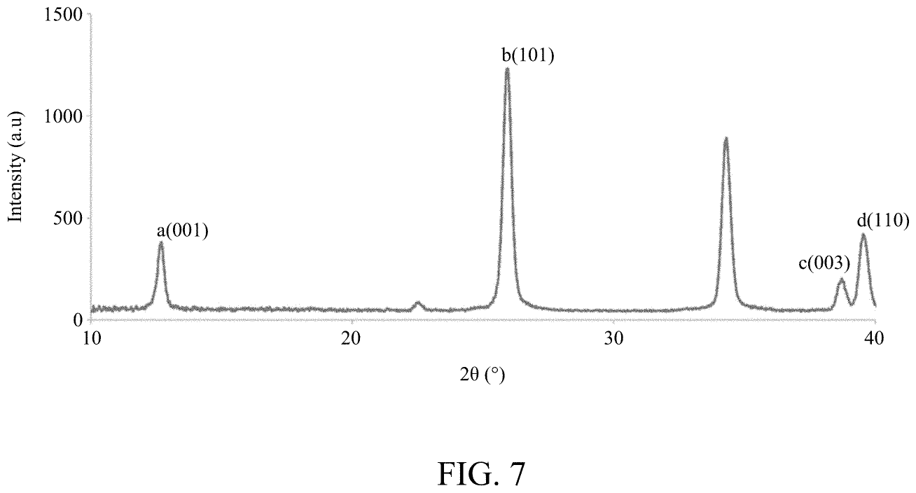

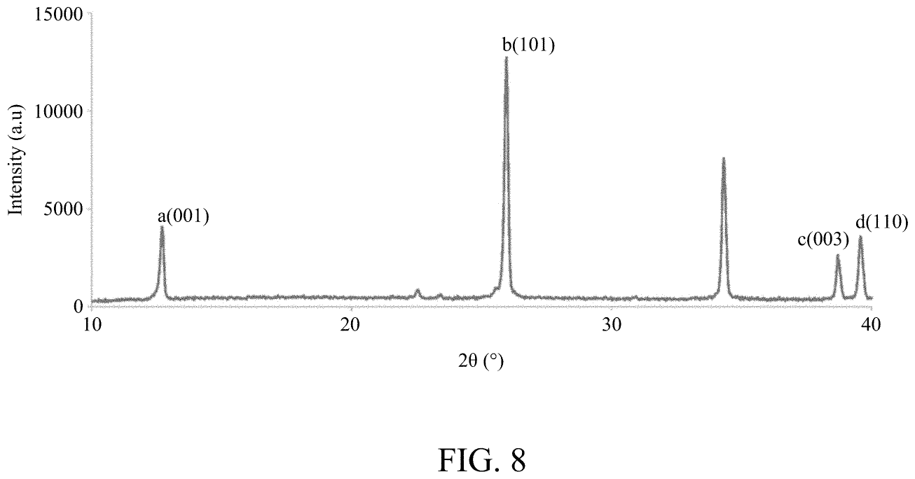

The Examples and Comparative examples were analyzed with a desktop X-ray diffractometer (purchased from Rigaku Company, Model: Miniflex II). The XRD patterns of lead iodide prepared in Examples 1 to 6 are shown in FIGS. 1 to 6 respectively and the XRD patterns of lead iodide prepared in Comparative examples 1 and 2 are shown in FIGS. 7 to 8 respectively. The ratio of c-peak intensity and d-peak intensity, and the ratio of a-peak intensity and b-peak obtained from the XRD patterns are also listed in Table 1 below.

TABLE 1

| | Example | Example | Example | Example | Example | Example | Comparative | Comparative |
|---|---|---|---|---|---|---|---|---|
| | 1 | 2 | 3 | 4 | 5 | 6 | example 1 | example 2 |
| pH value | 3 | 3 | 3 | 3 | 3 | 5 | 3 | 3 |
| Temperature | 160° C. | 120° C. | 100° C. | 80° C. | 60° C. | 120° C. | 40° C. | 25° C. |
| c-peak intensity: | 100:3 | 100:5 | 3:1 | 5:4 | 3:1 | 5:2 | 2:3 | 1:2 |
| d-peak intensity | | | | | | | | |
| a-peak intensity: | 50:3 | 100:3 | 2:1 | 5:6 | 2:3 | 10:1 | 1:5 | 1:4 |
| b-peak intensity | | | | | | | | |
| Crystal form | I | I | I | II | II | I | IV | IV |

It can be seen from the results of Examples 1 to 5 and Comparative examples 1 and 2 that the proportion of lead iodide crystal planes are controlled by the reaction temperature. When the temperature is 60° C. or above, the peak (c-peak) intensity of the (003) crystal plane is greater than or equal to the intensity of the peak (d-peak) of the (110) crystal plane; when the temperature is lower than 60° C., the intensity of the peak (c-peak) of the (003) crystal plane is less than the intensity of the peak (d-peak) of the (110) crystal plane; when the temperature is 100° C. or above, the peak (a-peak) intensity of the (001) crystal plane is greater than or equal to the peak (b-peak) intensity of the (101) crystal plane; when the temperature is lower than 100° C., the peak (a-peak) intensity of the (001) crystal plane is less than the peak (b-peak) intensity of the (101) crystal plane. In addition, the results of Examples 2 and 6 showed that a change of pH value within a certain range does not affect the result that the proportion of (003) crystal planes is greater than (110) crystal planes and the proportion of (001) crystal planes is greater than (101) crystal planes.

### Example 7

832.8 mg of the lead iodide prepared from Example 2, 117 mg of lead bromide, 295.5 mg of formamidine hydroiodide, 35.7 mg of methylammonium bromide, and 75 μl of 1.35 M (DMSO stock solution) of cesium iodide were taken and used as the raw materials of the ternary perovskite. The above raw materials were mixed with solvent: 300 μl of DMSO and 1200 μl of DMF, to formulate (FA_{0.8}MA_{0.15}Cs_{0.05})Pb(I_{0.85}Br_{0.15})₃ ternary perovskite precursor solution.

The ternary perovskite precursor solution was coated on a fluorine-doped tin oxide (FTO) substrate formed with titanium dioxide at a rotation speed of 4000 rpm, and an anti-solvent was added during the rotation, followed by annealing at 100° C. for 1 hour to form a ternary perovskite film. The annealed (FA_{0.8}MA_{0.15}Cs_{0.05})Pb(I_{0.85}Br_{0.15})₃ ternary perovskite film was coated with 2,2′,7,7′-tetrakis(N,N-di(4-methoxyphenyl)amino]-9,9′-spirobifluorene (spiro-OMeTAD) solution, then a gold electrode was formed by evaporation, and then a perovskite solar cell element was obtained.

### Examples 8 to 10 and Comparative Example 3

The perovskite solar cell elements were prepared according to the preparation method described in Example 7. The differences were in that the used lead iodide was prepared from different Examples, as shown in Table 2 below.

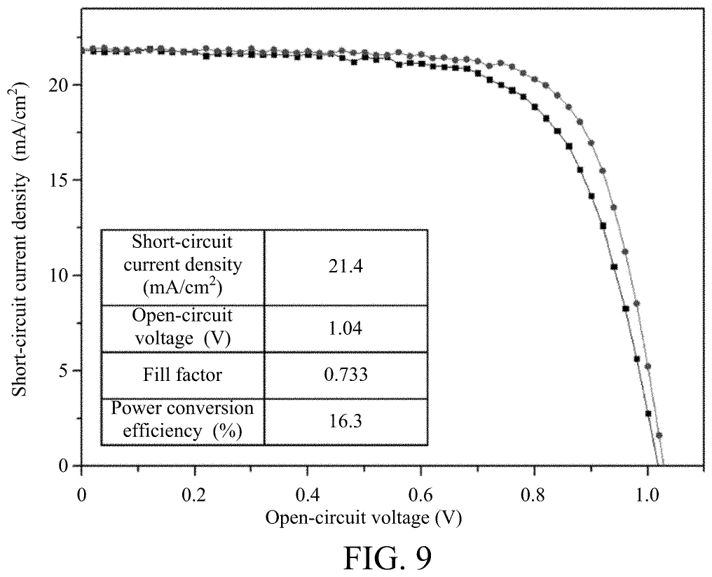

The perovskite solar cell elements of Examples 7 to 10 and Comparative example 3 were measured by AM 1.5 G solar simulator and Keithley 2400 multimeter, the measurement was ranged from −0.1 V to 1.2 V, the active area of the cell was 0.045 cm², and the results are shown in Table 2. In addition, FIG. 9 is a curve graph of short-circuit current density (Jsc) vs. open-circuit voltage (Voc) of the perovskite solar cell element of Example 7, wherein the square-dotted line and circle-dotted curve line are obtained respectively by the forward scan from a negative voltage to a positive voltage and by the reverse scan from a positive voltage to a negative voltage. The values are calculated by taking the average during the forward scan and reverse scan.

TABLE 2

| | | | | | Power |
|---|---|---|---|---|---|
| | | | | | conversion |
| | | Jsc | Voc | Fill factor | efficiency |
| | Lead iodide | (mA/cm²) | (V) | (FF) | (PCE, %) |
| Example 7 | Example 2 | 21.4 | 1.04 | 0.733 | 16.3 |
| Example 8 | Example 3 | 21.4 | 1.06 | 0.729 | 16.5 |
| Example 9 | Example 4 | 21.7 | 0.99 | 0.569 | 12.6 |
| Example 10 | Example 6 | 21.4 | 1.08 | 0.694 | 16.0 |
| Comparative | Comparative | 12.0 | 0.80 | 0.366 | 3.6 |
| example 3 | example 2 | | | | |

The results in Table 2 showed that using lead iodide having a specific crystal form as the raw material of ternary perovskite will enhance the ternary perovskite solar cell. Said specific crystal form meant that the proportion of (003) crystal planes is greater than the (110) crystal plane and this crystal form can be obtained by adjusting the temperature. More specifically, Type I crystal form: (003) crystal plane proportion is greater than (110) crystal plane proportion and (001) crystal plane proportion is greater than (101) crystal plane proportion, showed the best improvement which optimizing the efficiency of the ternary perovskite solar cell.

### Example 11

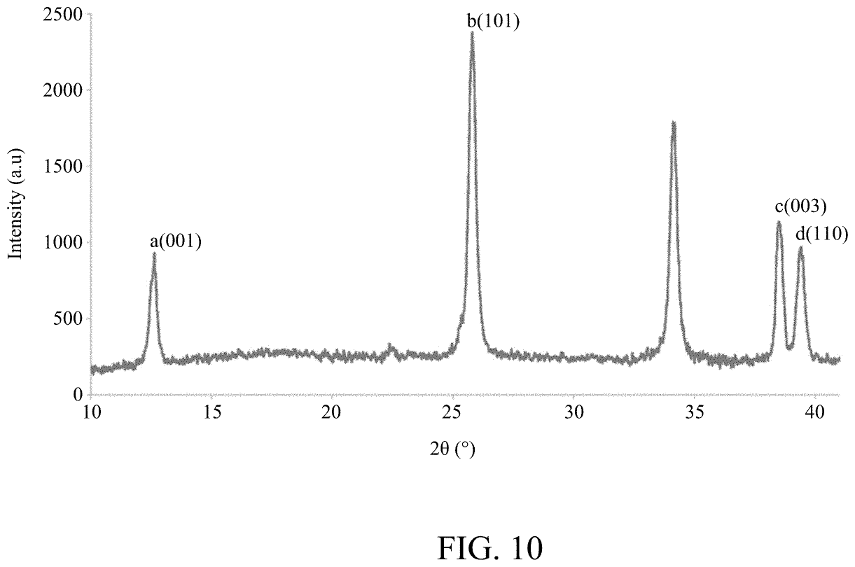

Lead iodide was prepared according to the preparation method described in Example 3, and the difference was in that the solution underwent continuously stirring during the cooling to room temperature. The XRD pattern of the lead iodide prepared in Example 11 is shown in FIG. 10, which showed that the intensity of the peak (c-peak) of the (003) crystal plane is greater than the intensity of the peak (d-peak) of the (110) crystal plane, and the intensity of the peak (a-peak) of the (001) crystal plane is less than the intensity of the peak (b-peak) of the (101) crystal plane, and this belongs to the Type II crystal form, which is different from the Type I crystal form of Example 3. It can be inferred that continuously stiffing the solution during the cooling period may hinder the crystallization and affect the formation of the specific crystal form.

### Example 12

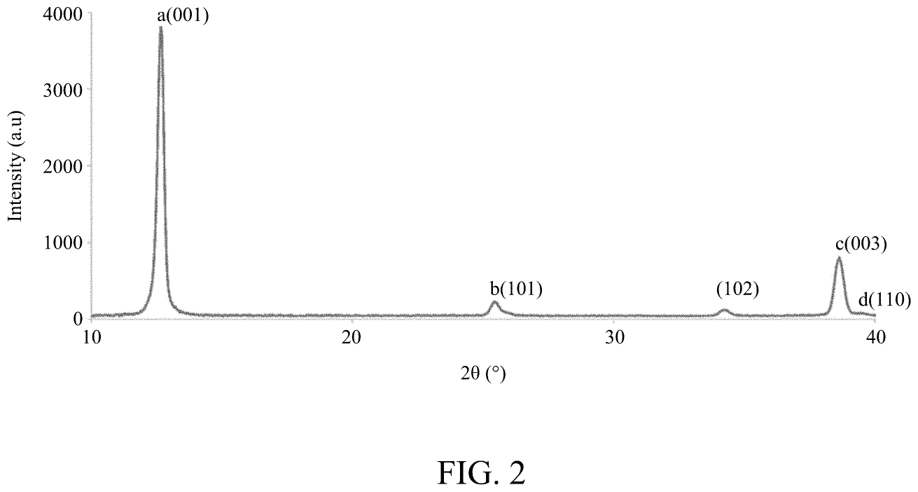

Lead iodide was prepared according to the preparation method described in Example 2, and the difference was in that after the first solution was formed, acetic acid as the second acid solution was not added, and the first solution was directly placed into the reactor, heated to 120° C. and the temperature was kept for 2 hours. The prepared lead iodide was subjected to XRD analysis, and the results showed that the lead iodide belongs to the Type I crystal form, which is the same as Example 2, and the XRD pattern is similar to that of FIG. 2.

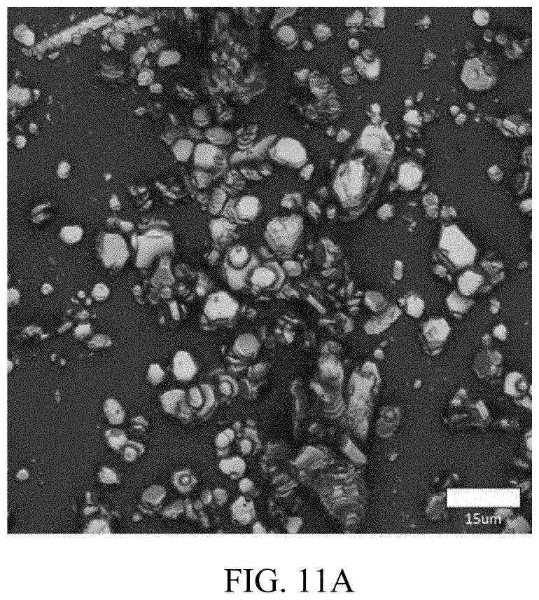

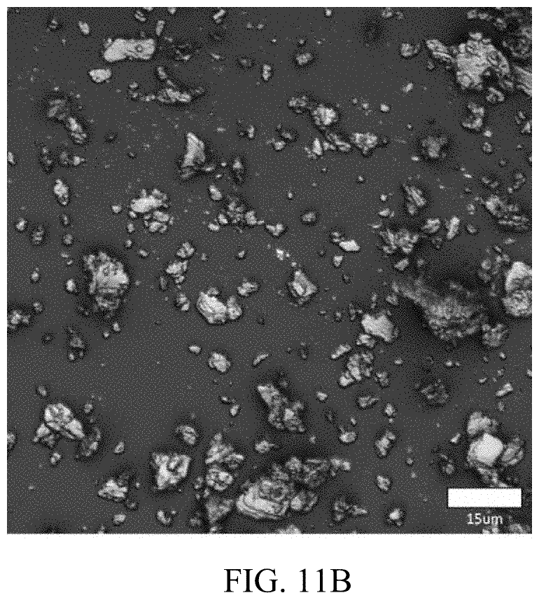

FIGS. 11A and 11B are microscope images of Example 2 and Example 12 (Olympus, model: LEXT OLS5000 3D Laser Scanning Confocal Microscope), respectively, to observe the effect of the addition of the second acid solution on the shape of the lead iodide crystal grains. The addition of the second acid solution has the characteristics of reducing the attachment of impurities to the lead iodide and making the lead iodide crystal more complete. Lead iodide belongs to a hexagonal crystal system (Hexagonal lattice), and the complete crystal is in a form of hexagonal. Therefore, it can be seen from FIGS. 11A and 11B that the lead iodide crystals formed by the addition of the second acid solution are more complete, whereas those formed without the addition of the second acid solution are more broken.

It will be apparent to those skilled in the art that various modifications and variations can be made to the disclosed embodiments. It is intended that the specification and examples be considered as exemplary only, with a true scope of the disclosure being indicated by the following claims and their equivalents

1. A method for preparing a lead iodide, comprising:
adding an iodine compound to a first acid solution, in which a lead compound is dissolved, to form a reaction solution comprising a first lead iodide; and
heating the reaction solution to a temperature of 60° C. or above and standing at a constant temperature, to obtain a second lead iodide,
wherein a peak intensity of a (003) crystal plane of the second lead iodide is greater than or equal to a peak intensity of a (110) crystal plane.

2. The method according to claim 1, wherein the temperature of the reaction solution is raised to 60° C. to 160° C.

3. The method according to claim 1, further comprising adding a second acid solution to the reaction solution after a formation of the first lead iodide and before heating the reaction solution.

4. The method according to claim 3, wherein the reaction solution containing the second acid solution comprises the first lead iodide at a concentration of less than 2 mM.

5. The method according to claim 1, wherein a pH value of the first acid solution is 1 to 5, and the first acid solution comprises acetic acid, hydrochloric acid, sulfuric acid, nitric acid, phosphoric acid, boric acid, or a combination thereof.

6. The method according to claim 1, wherein a time of standing at the constant temperature is between 1 to 3 hours.

7. The method according to claim 1, further comprising after standing at the constant temperature, standing to cool the reaction solution to 20° C. to 30° C., and rinsing the second lead iodide with water to neutral.

8. The method according to claim 1, wherein the lead compound comprises lead acetate, lead nitrate, lead hydroxide, lead oxide, lead chloride, lead carbonate, silicate lead, lead sulfate, or combinations thereof, and the iodine compound comprises potassium iodide, sodium iodide, lithium iodide, rubidium iodide, cesium iodide, strontium iodide, calcium iodide, barium iodide, magnesium iodide, or combinations thereof.

9. The method according to claim 1, wherein the iodine compound is dissolved in water before adding to the first acid solution.

10. The method according to claim 1, wherein the peak intensity of the (003) crystal plane of the second lead iodide relative to the peak intensity of the (110) crystal plane is 2.5 times or more.

11. The method according to claim 1, wherein a peak intensity of the (001) crystal plane of the second lead iodide is greater than or equal to a peak intensity of (101) crystal plane.

12. The method according to claim 13, wherein the peak intensity of the (001) crystal plane of the second lead iodide relative to the peak intensity of the (101) crystal plane is twice or more.

13. A preparation method of perovskite film comprising:
formulating a ternary perovskite precursor solution from a lead iodide, wherein a peak intensity of a (003) crystal plane of the lead iodide is greater than or equal to a peak intensity of a (110) crystal plane; and
coating the ternary perovskite precursor solution on a substrate to form a ternary perovskite film.

14. The method according to claim 13, wherein the lead iodide is obtained by the preparation method according to claim 1.

15. The method according to claim 13, wherein a peak intensity of the (001) crystal plane of the lead iodide is greater than or equal to a peak intensity of the (101) crystal plane.

16. The method according to claim 13, further comprising an anti-solvent process or a heating process to form the ternary perovskite film.

17. The method according to claim 13, wherein a ternary perovskite is represented by ABX₃, wherein
A is a monovalent cation comprising M₁, M₂ and M₃, wherein
M₁ is a C₁₋₂₀ alkyl or C₆₋₂₀ aryl substituted or unsubstituted amine compound,
M₂ is a C₁₋₂₀ alkyl or C₆₋₂₀ aryl substituted or unsubstituted amidine compound, and
M₃ is at least one selected from the group consisting of Cs, Rb, Li and Na;
B is Pb; and
X is at least one selected from the group consisting of halogen, SCN and OCN.

18. The method according to claim 13, wherein the ternary perovskite is (MAₓA_{y}Cs_{1-x-y})Pb(BrₐI₁₋ₐ)₃, wherein MA is CH₃NH₃⁺, FA is HC(═NH)NH₂⁺, 0<x<1, 0<y<1, 1-x-y is greater than 0, and 0≤a≤1.

19. The method according to claim 13, wherein the formulation of the ternary perovskite precursor solution comprising mixing lead iodide, lead bromide, formamidine hydroiodide, methylamine hydrobromide, and cesium iodine with a solvent.

20. The method according to claim 19, wherein the solvent is at least one selected from the group consisting of dimethyl sulfoxide, dimethylformamide, γ-butyrolactone, and N-methylpyrrolidone.
